(19) United States
(12) Patent Application Publication
(10) Pub. No.: US 2013/0001580 A1
(43) Pub. Date: Jan. 3, 2013

(54) THIN FILM TRANSISTOR AND ORGANIC LIGHT EMITTING DIODE DISPLAY USING THE SAME AND METHOD FOR MANUFACTURING THE SAME

(76) Inventors: Yong-Duck SON, Yongin-City (KR); Ki-Yong LEE, Yongin-City (KR); Jin-Wook SEO, Yongin-City (KR); Min-Jae JEONG, Yongin-City (KR); Tak-Young LEE, Yongin-City (KR)

(21) Appl. No.: 13/456,328

(22) Filed: Apr. 26, 2012

(30) Foreign Application Priority Data
Jun. 30, 2011 (KR) 10-2011-0065020

(51) Int. Cl. H01L 29/786; H01L 51/52; H01L 51/56; H01L 21/20

(52) U.S. Cl. 257/72; 257/66; 438/166; 438/34; 257/E29.292; 257/E51.018; 257/E21.09

(57) ABSTRACT

A thin film transistor includes an active layer on a substrate and crystallized through growth of crystals due to an action of metal catalysts, a gate insulating layer pattern on a part of the active layer; a gate electrode on a part of the gate insulating layer pattern; an anti-etching layer pattern formed on the gate insulating layer pattern to cover the gate electrode, the anti-etching layer pattern being coextensive with the gate insulating layer pattern; a source electrode and a drain electrode on the active layer and the anti-etching layer pattern; and gettering layer patterns between the active layer and the anti-etching layer pattern and between the source electrode and the drain electrode to eliminate the metal catalysts used for crystallization of the active layer, the gettering layer patterns being coextensive with the source electrode and drain electrode.

### RELATED APPLICATIONS

This application claims priority to and the benefit of Korean Patent Application No. 10-2011-0065020 filed in the Korean Intellectual Property Office on Jun. 30, 2011, the entire contents of which are incorporated herein by reference.

### BACKGROUND

1. Field

An exemplary described technology relates generally to a thin film transistor, a display device having the same, and a manufacturing method thereof. More particularly, the described technology relates generally to a thin film transistor structure that can be effectively used in a large-sized display device.

2. Description of the Related Art

Most flat panel display devices, such as an organic light emitting diode (OLED) display, a liquid crystal display (LCD), and the like, are manufactured through several thin film processes. Particularly, with excellent carrier mobility, a low temperature poly silicon thin film transistor (LTPS TFT) has been widely applicable.

The LTPS TFT uses a polysilicon layer formed by crystallizing an amorphous silicon layer as an active layer. A method for crystallization of the amorphous silicon layer includes a solid phase crystallization method, an excimer laser crystallization method, and a crystallization method using a metal catalyst.

The above information disclosed in this Background section is only for enhancement of understanding of the background of the described technology and therefore it may contain information that does not form the prior art that is already known in this country to a person of ordinary skill in the art.

### SUMMARY

According to an embodiment, there is provided a thin film transistor including an active layer on a substrate and crystallized through growth of crystals due to an action of metal catalysts, a gate insulating layer pattern on a part of the active layer, a gate electrode on a part of the gate insulating layer pattern, an anti-etching layer pattern formed on the gate insulating layer pattern to cover the gate electrode, the anti-etching layer pattern being coextensive with the gate insulating layer pattern, a source electrode and a drain electrode on the active layer and the anti-etching layer pattern, and gettering layer patterns between the active layer and the anti-etching layer pattern and between the source electrode and the drain electrode to eliminate the metal catalysts used for crystallization of the active layer, the gettering layer patterns being coextensive with the source electrode and drain electrode.

The metal catalysts may include nickel (Ni) and the gettering layer patterns include titanium (Ti).

An area of the active layer overlapped by the gate electrode may be a channel area. Areas of the active layer at sides of the channel area and contacting the source electrode and the drain electrode may be a source area and a drain area respectively.

The anti-etching layer pattern may have a different etching selectivity from etching selectivities of the gettering layer patterns, the source electrode, and the drain electrode.

According to an embodiment, there is provided a method for manufacturing a thin film transistor including preparing a substrate, forming an amorphous silicon layer on the substrate, applying metal catalysts above or below the amorphous silicon layer, forming a polysilicon layer by crystallizing the amorphous silicon layer through a growth of crystals from an action of the metal catalysts, forming an active layer by patterning the polysilicon layer, forming a gate insulating layer on a part of the active layer, forming a gate electrode on a part of the gate insulating layer, forming an anti-etching layer covering the gate insulating layer and the gate electrode, forming a gate insulating layer pattern and an anti-etching layer pattern that are coextensive with each other by patterning the gate insulating layer and the anti-etching layer together, forming a gettering layer on the active layer and the anti-etching layer pattern, forming a source-drain metal layer on the gettering layer, and forming a source electrode, a drain electrode, and a gettering layer pattern by patterning the gettering layer and the source-drain metal layer together.

The metal catalysts may include nickel (Ni) and the gettering layer pattern includes titanium (Ti).

The method for manufacturing the thin film transistor may further include forming an area of the active layer that is overlapped by the gate electrode as a channel area by doping the active layer with an impurity using the gate electrode as a mask, and forming a source area and a drain area respectively contacting the source electrode and the drain electrode at both sides of the channel area.

The anti-etching layer pattern may have a different etching selectivity from etching selectivities of the gettering layer, the source electrode, and the drain electrode.

According to an embodiment, there is provided a display device including an active layer on a substrate and crystallized through growth of crystals due to an action of metal catalysts, a gate insulating layer pattern on a part of the active layer, a gate electrode on a part of the gate insulating layer pattern, an anti-etching layer pattern formed with a same pattern as the gate insulating layer pattern, the anti-etching layer pattern being formed on the gate insulating layer pattern to cover the gate electrode, a source electrode and a drain electrode on the active layer and the anti-etching layer pattern, and gettering layer patterns between the active layer and the anti-etching layer pattern and between the source electrode and the drain electrode to eliminate the metal catalysts used for the crystallization of the active layer, the gettering layer patterns having a same pattern as patterns of the source electrode and the drain electrode, respectively.

The metal catalysts may include nickel (Ni) and the gettering layer patterns may include titanium (Ti).

An area of the active layer overlapped by the gate electrode may be a channel area. Areas at both sides of the channel area that respectively contact the source electrode and the drain electrode may be a source area and a drain area.

The display device may further include an organic light emitting diode on the substrate and connected with the drain electrode.

The anti-etching layer pattern may have a different etching selectivity from etching selectivities of the gettering layer, the source electrode, and the drain electrode.

According to an embodiment, there is provided a method for manufacturing a display device including preparing a substrate, forming an amorphous silicon layer on the substrate, applying metal catalysts above or below the amorphous silicon layer, forming a polysilicon layer by crystallizing the amorphous layer through growth of crystals from an action of the metal catalysts, forming an active layer by patterning the polysilicon layer, forming a gate insulating layer on a part of the active layer, forming a gate electrode on a part of the gate insulating layer, forming an anti-etching layer covering the gate insulating layer and the gate electrode, forming a gate insulating layer pattern and an anti-etching layer pattern that are coextensive with each other by patterning the gate insulating layer and the anti-etching layer together, forming a gettering layer on the active layer and the anti-etching layer pattern, forming a source-drain metal layer on the gettering layer, and forming a source electrode, a drain electrode, and a gettering layer pattern by pattering the gettering layer and the source-drain metal layer together.

The metal catalysts may include nickel (Ni) and the gettering layer pattern may include titanium (Ti).

The method for manufacturing the display device may further include forming an area of the active layer that is overlapped by the gate electrode as a channel area by doping the active layer with an impurity using the gate electrode as a mask, and forming a source area and a drain area respectively contacting the source electrode and the drain electrode at both sides of the channel area.

The method for manufacturing the display device may further include forming an organic light emitting diode connected with the drain electrode on the substrate.

The anti-etching layer pattern may have a different etching selectivity from etching selectivities of the gettering layer, the source electrode, and the drain electrode.

### BRIEF DESCRIPTION OF THE DRAWINGS

FIG. 1 illustrates a top plan view of a structure of a display device according to an exemplary embodiment.

FIG. 2 illustrates a circuit diagram of a pixel circuit of the display device of FIG. 1.

FIG. 3 illustrates an enlarged partial cross-sectional view of a thin film transistor of the display device of FIG. 1.

FIG. 4 to FIG. 11 illustrate cross-sectional views sequentially showing stages of a manufacturing process of the thin film transistor of FIG. 3.

### DETAILED DESCRIPTION

The embodiments will be described more fully hereinafter with reference to the accompanying drawings, in which exemplary embodiments of the invention are shown. As those skilled in the art would realize, the described embodiments may be modified in various different ways, all without departing from the spirit or scope of the present invention.

The drawings are schematic and not proportionally scaled down. Relative scales and ratios in the drawings are enlarged or reduced for the purpose of accuracy and convenience, and the scales are random and not limited thereto. In addition, like reference numerals designate like structures, elements, or parts throughout the specification. It will be understood that when an element is referred to as being “on” another element, it can be directly on another element or intervening elements may be present therebetween.

Exemplary views represent ideal exemplary embodiments in detail. Therefore, various modifications of diagrams are expected. Accordingly, exemplary embodiments are not limited to specific shapes of shown regions, and for example, also include modifications of the shape by manufacturing.

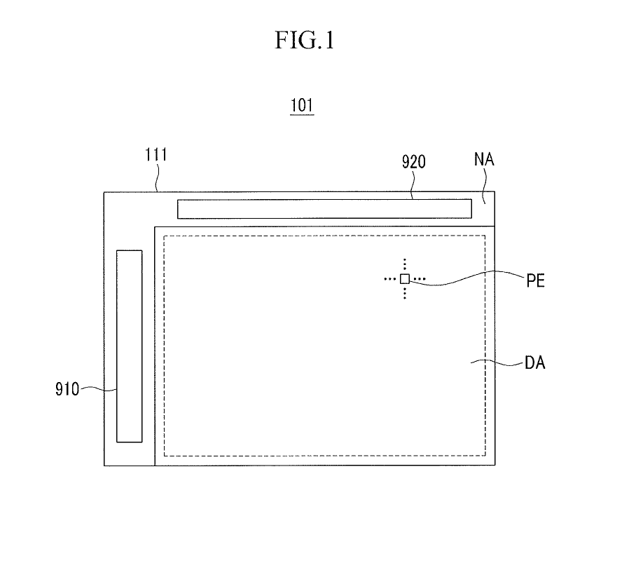

Hereinafter, a display device 101 including a thin film transistor 10 according to an exemplary embodiment will be described with reference to FIG. 1 to FIG. 3.

As shown in FIG. 1, the display device 101 may include a substrate main body 111 divided into a display area DA and a non-display area NA. A plurality of pixel areas PE may be formed in the display area DA of the substrate main body 111 to display an image, and one or more driving circuits 910 and 920 may be formed in the non-display area NA. Here, the pixel area PE refers to an area where a pixel is formed. The pixel is the minimum unit for displaying an image. However, it is not necessary for all the driving circuits 910 and 920 to be formed in the non-display area NA according to the exemplary embodiment, and the driving circuits 910 and 920 may be partially or entirely omitted.

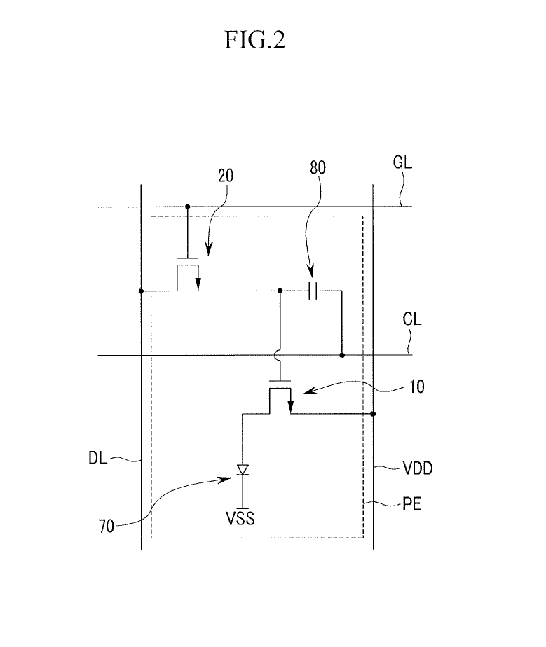

As shown in FIG. 2, the display device 101 according to the exemplary embodiment may have a structure in which each pixel PE has a 2Tr-1Cap structure with an organic light emitting diode 70, two thin film transistors (TFTs) 10 and 20, and a capacitor 80. Accordingly, the display device 101 may be an OLED display having a structure in which at least three thin film transistors and at least two capacitors are arranged in each pixel area PE. The display device 101 may include additional connecting lines such that the display device 101 has various structures. At least one of additionally formed thin film transistors and capacitors may provide a compensation circuit.

The compensation circuit may improve uniformity of the OLEDs 70 formed in the pixel areas PE so as to suppress image quality deviation. The compensation circuit may include two to eight thin film transistors.

The driving circuits 910 and 920 (shown in FIG. 1) formed on the non-display area NA of the substrate 111 may respectively include additional thin film transistors.

The OLED 70 may include an anode that is a hole injection electrode, a cathode that is an electron injection electrode, and an organic emission layer arranged between the anode and the cathode.

Specifically, in the first exemplary embodiment, the display device 101 may include a first thin film transistor 10 and a second thin film transistor 20 formed in each pixel area PE. The first thin film transistor 10 and the second thin film transistor 20 respectively may include gate electrodes, semiconductor layers, source electrodes, and drain electrodes.

FIG. 2 shows a gate line GL, a data line DL, a common power line VDD, and a capacitor line CL, but other structures are possible. Therefore, the capacitor line CL may be omitted as necessary.

The data line DL may be connected with a source electrode of the second thin film transistor 20, and the gate line GL may be connected with a gate electrode of the second thin film transistor 20. In addition, a drain electrode of the second thin film transistor 20 may be connected with the capacitor line CL through the capacitor 80. A node may be formed between the drain electrode of the second thin film transistor 20 and the capacitor 80, and the gate electrode of the first thin film transistor 10 may be connected thereto. The drain electrode of the first thin film transistor 10 may be connected with the common power line VDD, and the source electrode of the first thin film transistor 10 may be connected with an anode of the organic light emitting diode 70.

The second thin film transistor 20 may be used as a switch for selecting a pixel area PE for light emission. When the second thin film transistor 20 is turned on, the capacitor 80 may be instantly charged. At this time, the amount of the charge may be proportional to the potential of the voltage applied from the data line DL. When the second thin film transistor 20 turns off and signals are input into the capacitor line CL while increasing the voltage by a cycle of one frame, the gate potential of the first thin film transistor 10 may be increased along with the voltage applied through the capacitor line CL, based on the potential of the capacitor 80. When the gate potential of the first thin film transistor 10 goes over the threshold voltage, the second thin film transistor 20 turns on. Then, the voltage applied to the common power line VDD is applied to the organic light emitting diode 70 through the first thin film transistor 10 so that the organic light emitting diode 70 emits light.

The structure of the pixel PE may be variously modified.

Although it is not shown, the display device 101 according to the exemplary embodiment may be a liquid crystal display LCD. In this case, the display device 101 may include a liquid crystal layer, and may be formed in various structures known to a person skilled in the art.

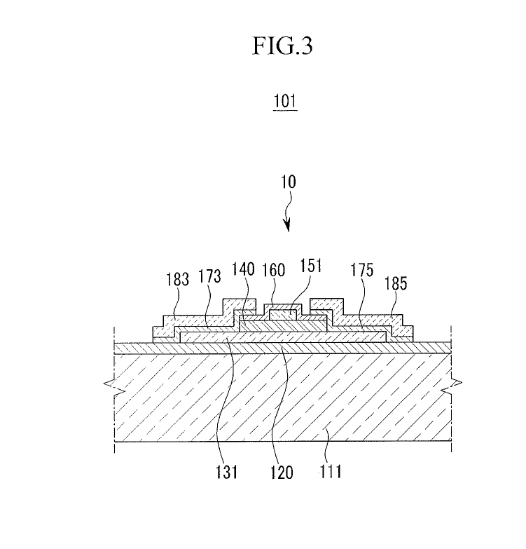

Hereinafter, a structure of the thin film transistors 10 and 20 according to the exemplary embodiment will be described in layering order with reference to FIG. 3. The thin film transistor 10 will be exemplarily described.

The substrate 111 may be formed of a transparent insulating substrate made of glass, quartz, ceramic, and plastic. The substrate 111 may be formed of other materials such as a metallic substrate made of stainless steel. In addition, if the substrate 111 is made of plastic, the substrate 111 may be a flexible substrate.

A buffer layer 120 may be formed on the substrate 111. The buffer layer 120 may be formed as a single-layered structure based on silicon nitride (SiNₓ), or a double-layered structure based on silicon nitride (SiNₓ) and silicon oxide (SiO₂). The buffer layer 120 may have a role of preventing unneeded components like impure elements or moisture from intruding into the target, while flattening the surface thereof. However, the buffer layer 120 may be omitted depending upon the kind and processing conditions of the substrate main body 111.

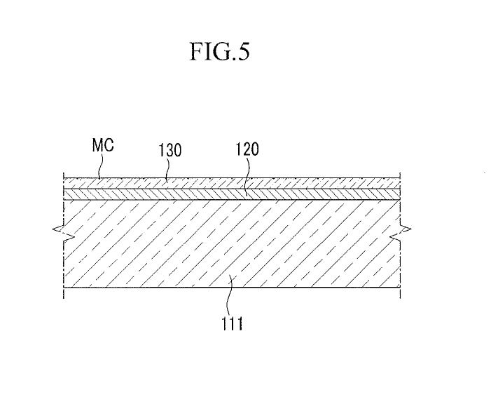

An active layer 131 may be formed on the buffer layer 120. The active layer 131 may be formed by patterning a polysilicon film 1300 (shown in FIG. 5). Here, the polysilicon film may be formed by crystallizing an amorphous silicon layer through growth of crystals due to an action of metal catalysts MC (shown in FIG. 5). For example, the metal catalysts MC may include nickel (Ni). In addition, a small amount of metal catalyst MC may remain in the active layer 131. With a crystallization method using the metal catalyst MC, an amorphous silicon film can be crystallized at a relatively low temperature with a relatively short period of time.

A gate insulating layer pattern 140 may be formed on the active layer 131. In further detail, the gate insulating layer pattern 140 may be formed on a part of the active layer 131. The gate insulating layer pattern 140 may partially cover the active layer 131.

The gate insulating layer pattern 140 may be formed by including one or more of various insulating materials, such as tetraethyl orthosilicate (TEOS), silicon nitride (SiNₓ), silicon oxide (SiO₂), and the like, known to the skilled person in the art.

A gate electrode 151 may be formed on the gate insulating layer pattern 140. In further detail, the gate electrode 151 may be formed on a part of the gate insulating layer pattern 140 formed on the active layer 131.

The gate electrode 151 may include at least one of various known metallic materials such as molybdenum (Mo), chromium (Cr), aluminum (Al), silver (Ag), titanium (Ti), tantalum (Ta), and tungsten (W).

An anti-etching layer pattern 160 may be formed on the gate electrode 151. The anti-etching layer pattern 160 may be formed to cover the gate electrode 151 on the gate insulating layer pattern 140. The anti-etching layer pattern 160 may be formed with the same pattern as the gate insulating layer pattern 140, interposing the gate electrode 151 between the anti-etching layer pattern 160 and the gate insulating layer pattern 140.

The anti-etching layer pattern 160 may be formed of an insulating material having different etching selectivity from etching selectivities of the gettering layer patterns 173 and 175, a source electrode 183, and a drain electrode 185. Here, the etching selectivity difference implies that the anti-etching layer pattern 160 is not etched when the gettering layer patterns 173 and 174, the source electrode 183, and the drain electrode 185 are etched.

The anti-etching layer pattern 160 may protect the gate electrode 151 and prevent the active layer 131 from being damaged from etching in a post process.

The gettering layer patterns 173 and 175 may be formed on the active layer 131 and the anti-etching layer pattern 160. The gettering layer patterns 173 and 175 may eliminate the metal catalyst MC used in the crystallization process of the active layer 131. For example, the gettering layer patterns 173 and 175 may include titanium (Ti).

In further detail, the gettering layer patterns 173 and 175 may be formed from above of the active layer 131, not being overlapped with the anti-etching layer pattern 160, to above of the anti-etching layer pattern 160. Further, the gettering layer patterns 173 and 175 may be separated from each other, interposing the gate electrode 151 therebetween. The gettering layer patterns 173 and 175 may be separated from each other, interposing a predetermined space disposed on the gate electrode 151.

In addition, the gettering layer pattern 173 and 175 may function to reduce contact resistance between the source electrode 184 and the drain electrode 185 to be formed on the gettering layer patterns 173 and 175 and the active layer 131.

Further, the gettering layer patterns 173 and 175 may be formed without performing processes that may be insufficient to a large-sized process, such as an ion shower process or an ion implantation process. Thus, the display device 101 according to the exemplary embodiment may be relatively easily manufactured, even though the size of the display device 101 is increased.

The source electrode 183 and the drain electrode 185 may be respectively formed on the gettering layer patterns 173 and 175. In further detail, the source electrode 183 and the drain electrode 185 may be respectively formed with the same pattern of those of the gettering layer patterns 173 and 175. Thus, like the gettering layer patterns 173 and 175, the source electrode 183 and the drain electrode 185 may also be separated from each other, interposing the gate electrode 151.

The active layer 131, the gate electrode 151, the source electrode 183, and the drain electrode 185 may form the thin film transistor 10.

In addition, another display device 101 according to the exemplary embodiment may include a thin film transistor 10 having an offset structure in which a source electrode 183 and a drain electrode 185 are separated in a horizontal direction from a gate electrode 151 and thus they do not overlap the gate electrode 151. As described, when the thin film transistor 10 is formed with an offset structure, the leakage current may be decreased. Further, the anti-etching layer pattern 160 may prevent the active layer 131 from being partially etched and thus being damaged when the source electrode 183 and the drain electrode 185 are patterned to be separated in a horizontal direction from the gate electrode 151.

In addition, the source electrode 183 and the drain electrode 185 may be formed of various metallic materials known to a person skilled in the art.

With such a configuration, the display device 101 according to the exemplary embodiment can be effectively increased in size while including the thin film transistor 10 that has the active layer 131 crystallized through a crystallization method using the metal catalysts MC. The display device 101 may be manufactured without using an ion shower process or an ion implantation process that is disadvantageous to a large scale process, even though the display device 101 uses the polysilicon thin film transistor. In addition, the display device 101 may include the active layer 131 effectively crystallized using the metal catalysts MC.

Further, the display device 101 can be stably manufactured by preventing over-etching.

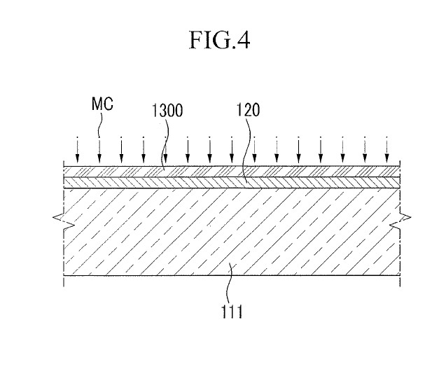

Hereinafter, a manufacturing method of a display device 101 according to an exemplary embodiment will be described with reference to FIG. 4 to FIG. 10. The description will be focused on a thin film transistor 10.

First, as shown in FIG. 4, a buffer layer 120 and an amorphous layer 1300 may be formed on a substrate 111.

The buffer layer 120 may be as a single-layered structure based on silicon nitride (SiNₓ), or a double-layered structure based on silicon nitride (SiNₓ) and silicon oxide (SiO₂).

Next, metal catalysts MC may be sprayed on the amorphous silicon layer 1300.

For example, the metal catalyst MC may be sprayed with a dose amount in a range of about 1.0 e¹⁰ atoms/cm² to about 1.0 e¹⁴ atoms/cm². A small amount of the metal catalyst MC may be sprayed such that a molecular unit may be the smallest unit on the amorphous silicon layer 1300.

Further, the metal catalyst MC may be sprayed on the buffer layer 120 before the amorphous silicon layer 1300 is formed. The metal catalyst MC may be sprayed first, and then the amorphous silicon layer 1300 may be formed.

Next, when the amorphous silicon layer 1300 is heat-treated, crystals may be grown by action of the metal catalyst MC sprayed on the amorphous silicon layer 1300, and as shown in FIG. 5, the amorphous silicon layer 1300 may become a polysilicon layer 130.

For example, in a crystallization process of the amorphous silicon layer 1300 using nickel (Ni) as the metal catalyst MC, nickel (Ni) may be combined with silicon (Si) of the amorphous silicon layer 1300 such that nickel disilicide (NiSi₂) is formed. The nickel disilicide (NiSi₂) becomes a seed and the crystals may be grown around the seed.

As described, a crystallization method using the metal catalyst MC can crystallize the amorphous silicon layer 1300 with a relatively short period of time at a relatively low temperature.

Further, the polysilicon layer 130 crystallized through the metal catalyst MC may have grains with a size of several tens of μm. In addition, a plurality of sub-grain boundaries may exist in each grain boundary. Accordingly, deterioration of uniformity due to the grain boundary can be minimized.

As described, the thin film transistor 10 using the polysilicon layer 130 crystallized through the metal catalyst MC may have a relatively high current driving capability, that is, a high electron mobility. However, due to residual metal catalysts MC in the polysilicon layer 130, the thin film transistor 10 may have a relatively high leakage current. Therefore, it is desirable to minimize the residual metal catalysts MC in the polysilicon layer 130 by removing the metal catalysts MC.

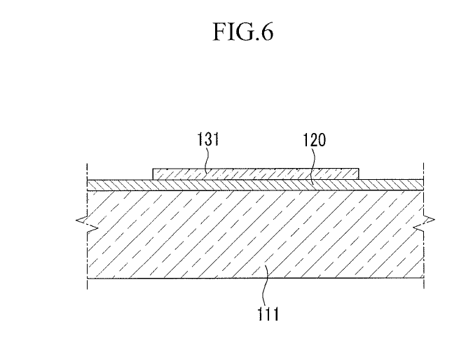

Next, as shown in FIG. 6, an active layer 131 may be formed by patterning the polysilicon layer 1300. The active layer 131 may be patterned through a photolithography process.

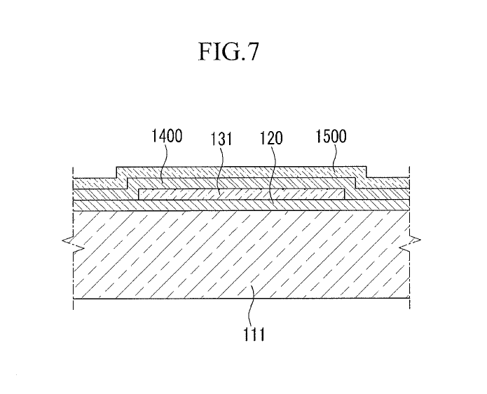

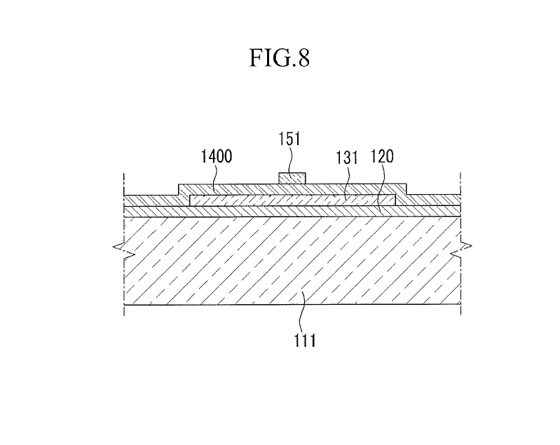

Then, as shown in FIG. 7, a gate insulating layer 1400 and a gate metal layer 1500 may be formed on the active layer 131. A gate electrode 151 may be formed by patterning the gate metal layer 500, as shown in FIG. 8. The gate electrode 151 may be patterned through a photolithography process.

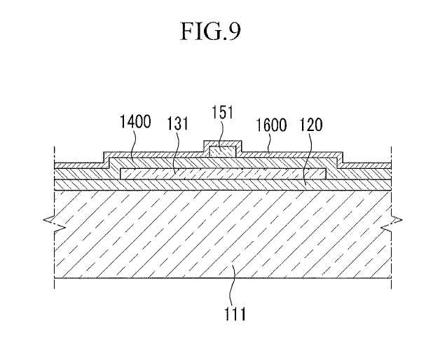

Next, as shown in FIG. 9, an anti-etching layer 1600 may be formed on the gate electrode 151 over the gate insulating layer 1400. The anti-etching layer 1600 may be formed of a material having a different etching selectivity from etching selectivities of gettering layer patterns 173 and 175, a source electrode 183, and a drain electrode 185.

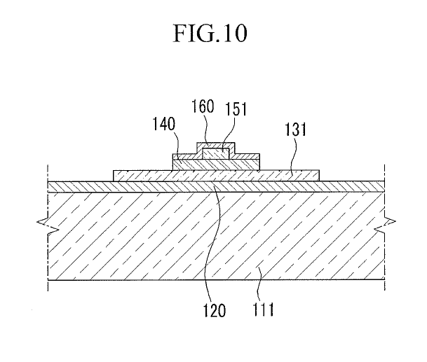

Next, as shown in FIG. 10, the anti-etching layer 1600 and the gate insulating layer 1400 may be patterned together to form an anti-etching layer pattern 160 and a gate insulating layer pattern 140. In this case, the gate insulating layer pattern 140 may be formed on a part of the active layer 131. The anti-etching layer pattern 160 may be formed with the same pattern of the gate insulating layer pattern 140, interposing the gate electrode 151 between the anti-etching layer pattern 160 and the gate insulating layer pattern 140. In this case, the anti-etching layer pattern 160 and the gate insulating layer pattern 140 may be patterned through a photolithography process.

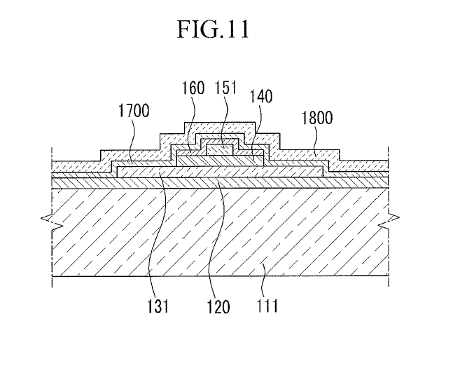

Next, as shown in FIG. 11, a gettering layer 1700 and a source-drain metal layer 1800 may be formed on the anti-etching layer pattern 160.

Then, residual metal catalysts MC in the active layer 131 may be eliminated by heat-treating the gettering layer 1700. After this process, some of the metal catalysts MC may still remain. As a residual amount of the metal catalysts is increased, the leakage current may be increased, and therefore it is desirable to eliminate the metal catalysts MC as much as possible.

Next, the gettering layer 1700 and the source-drain metal layer 1800 may be patterned together to form the gettering layer patterns 173 and 175, the source electrode 183, and the drain electrode 185, as previously described with reference to FIG. 3. The gettering layer patterns 173 and 175, the source electrode 183, and the drain electrode 185 may be patterned through a photolithography process. The photolithography process may include a double exposure process or a half-tone exposure process.

The source electrode 183 and the drain electrode 185 may be formed on the part of the active layer 131 that is not overlapped by the anti-etching layer pattern 160 and over the anti-etching layer pattern 160. Further, the source electrode 183 and the drain electrode 185 may be separated from each other, interposing the gate electrode 151 therebetween.

The gettering layer patterns 173 and 175 may be formed with the same patterns of the source electrode 183 and the drain electrode 185. Thus, like the source electrode 183 and the drain electrode 185, the gettering layer patterns 173 and 175 may be separated from each other.

In addition, the source electrode 183 and the drain electrode 185 may be separated from the gate electrode 151 in the horizontal direction. The anti-etching layer pattern 160 prevents damage to the active layer 131 when the source electrode 183 and the drain electrode 185 are patterned to be separated from the gate electrode 151 in the horizontal direction. The anti-etching layer pattern 160 may be disposed under ends of the gettering layer patterns 173 and 175, the source electrode 183, and the drain electrode 185 that are disposed on the active layer 131. Therefore, the anti-etching layer pattern 160 may prevent over-etching in the etching process to protect the active layer 131.

In addition, the anti-etching layer pattern 160 may protect the gate electrode 151 in a process for forming the gettering layer patterns 173 and 175, the source electrodes 183, and the drain electrode 185.

Further, the gettering layer patterns 173 and 175 may function to reduce contact resistance between the source electrode 183, the drain electrode 185, and the active layer 131. Thus, an ion shower process or an ion implantation process that cannot be easily used in a large scale process can be omitted in the manufacturing process of the display device 101.

By way of summation and review, among various crystallization methods, a crystallization method using a metal catalyst can reduce a crystallization process time compared to a solid phase crystallization method, and can be processed at a relatively low temperature. Further, the crystallization method using a metal catalyst is advantageous to a manufacturing process of a large-sized display device compared to the excimer laser crystallization method. Thus, a thin film transistor having a structure that can be effectively manufactured through a large scale process using the crystallization method using the metal catalyst is desirable.

Through such a manufacturing method as described herein, the display device 101 according to the exemplary embodiment can be manufactured. The display device can be effectively increased in size while including the thin film transistor 10 having the active layer 131 through the crystallization method using the metal catalysts MC. The display device 101 may be manufactured without using the ion shower process or the ion implantation process that may be disadvantageous to the large-scale process while using the polysilicon thin film transistor. Further, the display device 101 may include the active layer 131 effectively crystallized using the metal catalysts MC. In addition, the display device 101 can be stably manufactured while preventing over-etching.

Accordingly, embodiments disclosed herein may provide a thin film transistor that can be effectively used in a relatively large-sized display device while having an active layer crystallized through a crystallization method using metal catalyst. Further, a large-sized display device can be effectively manufactured using the above-described thin film transistor.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor comprising:
an active layer on a substrate and crystallized through growth of crystals due to an action of metal catalysts;
a gate insulating layer pattern on a part of the active layer;
a gate electrode on a part of the gate insulating layer pattern;
an anti-etching layer pattern formed on the gate insulating layer pattern to cover the gate electrode, the anti-etching layer pattern being coextensive with the gate insulating layer pattern;
a source electrode and a drain electrode on the active layer and the anti-etching layer pattern; and
gettering layer patterns between the active layer and the anti-etching layer pattern and between the source electrode and the drain electrode to eliminate the metal catalysts used for crystallization of the active layer, the gettering layer patterns being coextensive with the source electrode and drain electrode.

2. The thin film transistor of claim 1, wherein the metal catalysts include nickel (Ni) and the gettering layer patterns include titanium (Ti).

3. The thin film transistor of claim 1, wherein:
an area of the active layer overlapped by the gate electrode is a channel area, and
areas of the active layer at sides of the channel area and contacting the source electrode and the drain electrode are a source area and a drain area respectively.

4. The thin film transistor of claim 1, wherein the anti-etching layer pattern has a different etching selectivity from etching selectivities of the gettering layer patterns, the source electrode, and the drain electrode.

5. A method for manufacturing a thin film transistor comprising:
preparing a substrate;
forming an amorphous silicon layer on the substrate;
applying metal catalysts above or below the amorphous silicon layer;
forming a polysilicon layer by crystallizing the amorphous silicon layer through a growth of crystals from an action of the metal catalysts;
forming an active layer by patterning the polysilicon layer;
forming a gate insulating layer on a part of the active layer;
forming a gate electrode on a part of the gate insulating layer;
forming an anti-etching layer covering the gate insulating layer and the gate electrode;
forming a gate insulating layer pattern and an anti-etching layer pattern that are coextensive with each other by patterning the gate insulating layer and the anti-etching layer together;
forming a gettering layer on the active layer and the anti-etching layer pattern;
forming a source-drain metal layer on the gettering layer; and
forming a source electrode, a drain electrode, and a gettering layer pattern by patterning the gettering layer and the source-drain metal layer together.

6. The method for manufacturing the thin film transistor of claim 5, wherein the metal catalysts include nickel (Ni) and the gettering layer pattern includes titanium (Ti).

7. The method for manufacturing the thin film transistor of claim 5, further comprising forming an area of the active layer that is overlapped by the gate electrode as a channel area by doping the active layer with an impurity using the gate electrode as a mask, and forming a source area and a drain area respectively contacting the source electrode and the drain electrode at both sides of the channel area.

8. The method for manufacturing the thin film transistor of claim 5, wherein the anti-etching layer pattern has a different etching selectivity from etching selectivities of the gettering layer, the source electrode, and the drain electrode.

9. A display device comprising:
an active layer on a substrate and crystallized through growth of crystals due to an action of metal catalysts;
a gate insulating layer pattern on a part of the active layer;
a gate electrode on a part of the gate insulating layer pattern;
an anti-etching layer pattern formed with a same pattern as the gate insulating layer pattern, the anti-etching layer pattern being formed on the gate insulating layer pattern to cover the gate electrode;
a source electrode and a drain electrode on the active layer and the anti-etching layer pattern; and
gettering layer patterns between the active layer and the anti-etching layer pattern and between the source electrode and the drain electrode to eliminate the metal catalysts used for the crystallization of the active layer, the gettering layer patterns having a same pattern as patterns of the source electrode and the drain electrode, respectively.

10. The display device of claim 9, wherein the metal catalysts include nickel (Ni) and the gettering layer patterns include titanium (Ti).

11. The display device of claim 9, wherein:
an area of the active layer overlapped by the gate electrode is a channel area, and
areas at both sides of the channel area that respectively contact the source electrode and the drain electrode are a source area and a drain area.

12. The display device of claim 9, further comprising an organic light emitting diode on the substrate and connected with the drain electrode.

13. The display device of claim 9, wherein the anti-etching layer pattern has a different etching selectivity from etching selectivities of the gettering layer, the source electrode, and the drain electrode.

14. A method for manufacturing a display device comprising:
preparing a substrate;
forming an amorphous silicon layer on the substrate;
applying metal catalysts above or below the amorphous silicon layer;
forming a polysilicon layer by crystallizing the amorphous layer through growth of crystals from an action of the metal catalysts;
forming an active layer by patterning the polysilicon layer;
forming a gate insulating layer on a part of the active layer;
forming a gate electrode on a part of the gate insulating layer;
forming an anti-etching layer covering the gate insulating layer and the gate electrode;
forming a gate insulating layer pattern and an anti-etching layer pattern that are coextensive with each other by patterning the gate insulating layer and the anti-etching layer together;
forming a gettering layer on the active layer and the anti-etching layer pattern;
forming a source-drain metal layer on the gettering layer; and
forming a source electrode, a drain electrode, and a gettering layer pattern by pattering the gettering layer and the source-drain metal layer together.

15. The method for manufacturing the display device of claim 14, wherein the metal catalysts include nickel (Ni) and the gettering layer pattern includes titanium (Ti).

16. The method for manufacturing the display device of claim 14, further comprising forming an area of the active layer that is overlapped by the gate electrode as a channel area by doping the active layer with an impurity using the gate electrode as a mask, and forming a source area and a drain area respectively contacting the source electrode and the drain electrode at both sides of the channel area.

17. The method for manufacturing the display device of claim 14, further comprising forming an organic light emitting diode connected with the drain electrode on the substrate.

18. The method for manufacturing the display device of claim 14, wherein the anti-etching layer pattern has a different etching selectivity from etching selectivities of the gettering layer, the source electrode, and the drain electrode.
